(19) United States
(12) Patent Application Publication
(10) Pub. No.: US 2020/0204926 A1
(43) Pub. Date: Jun. 25, 2020

(54) ULTRA-LOW DISTORTION MICROPHONE BUFFER

(71) Applicant: WIZEDSP LTD., TEL-AVIV (IL)

(72) Inventor: OZ GABAI, TEL-AVIV (IL)

(21) Appl. No.: 15/752,907

(22) PCT Filed: Aug. 18, 2016
(86) PCT No.: PCT/IB2016/054950

§ 371 Date: Feb. 15, 2018

Related U.S. Application Data
(60) Provisional application No. 62/206,705, filed on Aug. 18, 2015.

(51) Int. Cl. H04R 19/04; H04R 19/01; H04R 29/00; H03G 3/30

(52) U.S. Cl. CPC H04R 19/04; H04R 19/01; H04R 29/004; H03G 2201/103; H04R 2201/003; H04R 2410/03; H03G 3/3005

(57) ABSTRACT

An acoustic sensor including a fixed conductive plate and an elastic conductive plate placed in parallel, an electric circuit connected to the fixed conductive plate and to the elastic conductive plate and providing a signal indicating temporal capacitance between the fixed conductive plate and to the elastic conductive plate, a controller including an input terminal connected to the electric circuit and an output terminal providing gain-control output signal, and a variable-gain amplifier including a first input terminal connected to the at least one fixed conductive plate, a second input terminal connected to the elastic conductive plate, a gain-control input terminal connected to the controller output, and an output terminal providing the sensed acoustic signal.

### CROSS-REFERENCE TO RELATED APPLICATIONS

This application claims the benefit of U.S. Provisional Application No. 62/206,705, filed Aug. 18, 2015, the disclosures of which is incorporated herein by reference in their entirety.

### FIELD

The method and apparatus disclosed herein are related to the field of acoustic sensors, and particularly microphones, and, more particularly but not exclusively, to ultra-low distortion microphones and microphone circuitry, for example using an electret condenser microphone (ECM), or Micro Electronic Mechanical Systems (MEMS) microphone.

### BACKGROUND

Today, 2015, microphones are used nearly anywhere, in smartphones (with about three microphones per smartphone), cell phones, wireless (e.g., Bluetooth) and wired earpieces, toys, etc., selling billions of microphones each year. The number of devices connected to the internet is growing each year, including air conditioners, washing machines, TV sets, electric water boilers, etc. Connecting the electric water boiler, washing machine, and drying machine to the internet may help us save money by using lower electricity rates. A smart home may have a “brain” running in internet servers using neural network and artificial intelligence algorithms to smartly operate home appliances. Having sensors installed in the house reporting to this “brain” through the internet, can save us much time and money.

A battery-based electricity generator may charge the house battery when there is a low demand, and release power when demand and prices are high. To have the current rate data, the battery-based generator must be connected to the electricity utility server via the internet. The times/rates data may enable the system to maximize the efficiency of the generator plan to save money.

Some of the benefits of connecting a device to the internet are: The ability to smart control the device—having the brain on the net. The ability to manually control each device using a remote control, a smartphone, a tablet computer, etc. The ability to observe, collect, and log information about the device, for a service like an off date usage. The ability to search and locate devices. The ability to provide a better service by collecting and analyzing information received from the usage of each device like a toothbrush or a screw driver. The ability to get better price for products and services.

Connecting devices to the internet can make our lives much more efficient. The technology is rapidly advancing every day, and some have forecasted that by 2020, more than 50,000,000,000 devices would be connected to the internet. Some of these devices will probably be light bulbs, light switches, air conditioning systems, tools such as screwdrivers, toothbrushes, medical devices such as portable blood pressure measurement devices, books and toys.

IoT (Internet of Things), or IoE (Internet of Everything) devices connected to the internet, may have a local power source. IoT devices may use Wi-Fi, Bluetooth (BT), ZigBee or any other wireless communication standard, or Power Line Communication (PLC) technology, to connect the device to the local home router, and hence to the internet. Some devices such as glasses, tools, clothes, bathroom portable devices such as toothbrush, and toys may require batteries as their energy source. However, if the wireless communication is implemented using electromagnetic radio frequency communication, then power becomes a big issue. Such battery operated receivers, in order to keep battery life as long as possible, will periodically turn on for a short time, in order to check for incoming messages. Another option to operate a low power receiver, would incorporate a wakeup receiver that detects a presence of energy in some band, and then checks if it is a valid marker. This two-step process may save power, as the marker check is done only when a signal is detected. However, the ISM band, or any other high bandwidth radio frequency, has much noise, which makes the two-step solution useless.

There is thus a widely recognized need for, and it would be highly advantageous to have, a system and method for acoustic sensors and related circuitry that overcomes the above limitations.

### SUMMARY

According to one exemplary embodiment, there is provided a method, and a device providing an acoustic sensor including at least one fixed conductive plate and an elastic conductive plate placed in parallel, an electric circuit connected to the fixed conductive plate and to the elastic conductive plate and providing a signal indicating temporal capacitance between the fixed conductive plate and to the elastic conductive plate, a controller including an input terminal connected to the electric circuit and an output terminal providing gain-control output signal, and a variable-gain amplifier including a first input terminal connected to the at least one fixed conductive plate, a second input terminal connected to the elastic conductive plate, a gain-control input terminal connected to the controller output, and an output terminal providing the sensed acoustic signal.

According to another exemplary embodiment, electret is placed between the fixed conductive plate and the elastic conductive plate forming Electrets Condenser Microphone.

According to still another exemplary embodiment, the acoustic sensor includes a fixed conductive plate and an elastic conductive plate placed in parallel, a variable-gain amplifier including a first input terminal connected to the at least one fixed conductive plate, a second input terminal connected to the elastic conductive plate, a gain-control input terminal, and an output terminal, a first impedance connected between one of the conductive plates and a bias voltage, a second impedance connected between another of the conductive plates and a test signal generator, and a controller including an input terminal connected to the connection between the second impedance and the other conductive plate, and an output terminal connected to the gain-control input of the variable-gain amplifier.

Further according to another exemplary embodiment the first impedance includes one or more resistors, and/or one or more low-leakage diodes, and/or a plurality of low-leakage diodes connected in series, and/or a pair of low-leakage diodes connected in parallel in opposite polarity, and/or a plurality of pairs of low-leakage diodes where each pair of low-leakage diodes includes two diodes connected in parallel in opposite polarity, and where the pairs of low-leakage diodes are connected in series, and/or a plurality of pairs of low-leakage diodes where each pair of low-leakage diodes includes two diodes connected in parallel in opposite polarity, where the pairs of low-leakage diodes are connected in series, and where the plurality of pairs of low-leakage diodes is connected in parallel to a capacitor.

Still further according to another exemplary embodiment the second impedance includes one or more resistors, and/or an inductor.

Yet further according to another exemplary embodiment the controller calculates the gain-control output signal according to the inverse of distortion gain.

Even further according to another exemplary embodiment the controller measures base-capacitance when no pressure is applied to the elastic plate and calculates temporal-distortion-gain based on the base-capacitance.

Additionally, according to another exemplary embodiment, the distortion gain is calculated according to 1+f(P), where f(P)=f₁(C) is the distortion element, which is calculated using a measurement of the temporal capacitance and plates geometry of the acoustic sensor.

Unless otherwise defined, all technical and scientific terms used herein have the same meaning as commonly understood by one of ordinary skill in the relevant art. The materials, methods, and examples provided herein are illustrative only and not intended to be limiting. Except to the extent necessary or inherent in the processes themselves, no particular order to steps or stages of methods and processes described in this disclosure, including the figures, is intended or implied. In many cases the order of process steps may vary without changing the purpose or effect of the methods described.

### BRIEF DESCRIPTION OF THE DRAWINGS

Various embodiments are described herein, by way of example only, with reference to the accompanying drawings. With specific reference now to the drawings in detail, it is stressed that the particulars shown are by way of example and for purposes of illustrative discussion of the preferred embodiments only, and are presented in order to provide what is believed to be the most useful and readily understood description of the principles and conceptual aspects of the embodiment. In this regard, no attempt is made to show structural details of the embodiments in more detail than is necessary for a fundamental understanding of the subject matter, the description taken with the drawings making apparent to those skilled in the art how the several forms and structures may be embodied in practice.

In the drawings:

FIG. 1 is a simplified block diagram of a wakeup receiver circuit;

FIG. 2 is a simplified state machine of an acoustic wakeup transceiver;

FIG. 3A is a simplified illustration of a round-plates MEMS microphone capacitor element;

FIG. 3B is a simplified illustration of a square-plates MEMS microphone capacitor element;

FIG. 3C is a simplified illustration of a side view of MEMS capacitor element at rest;

FIG. 3D is a simplified illustration of a side view of MEMS capacitor when pressure is applied to the elastic conductive plate;

FIG. 4 is a simplified illustration of an electronic circuit providing a dynamic model of a capacitor based Microphone (MEMS or ECM) upper plate;

FIG. 5 is a simplified illustration of an ultra-low distortion microphone buffer basic diagram; and

FIG. 6 is a simplified illustration of an ultra-low distortion microphone buffer circuit.

### DETAILED DESCRIPTION

The present embodiments comprise a method and/or a device including an acoustic sensor, and particularly a microphone, and/or electric circuitry for a microphone, more particularly but not exclusively, an ultra-low-distortion microphone, and/or microphone buffer.

The principles and operation of the devices and methods according to the several exemplary embodiments presented herein may be better understood with reference to the following drawings and accompanying description.

Before explaining at least one embodiment in detail, it is to be understood that the embodiments are not limited in its application to the details of construction and the arrangement of the components set forth in the following description or illustrated in the drawings. Other embodiments may be practiced or carried out in various ways. Also, it is to be understood that the phraseology and terminology employed herein is for the purpose of description and should not be regarded as limiting.

In this document, an element of a drawing that is not described within the scope of the drawing and is labeled with a numeral that has been described in a previous drawing has the same use and description as in the previous drawings. Similarly, an element that is identified in the text by a numeral that does not appear in the drawing described by the text, has the same use and description as in the previous drawings where it was described.

The drawings in this document may not be to any scale. Different figures may use different scales and different scales can be used even within the same drawing, for example different scales for different views of the same object or different scales for the two adjacent objects.

The purpose of the embodiments is to provide at least one system and/or method for sensing acoustic signals, and particularly a microphone and/or microphone buffer, operating in ultra-low-power, and/or an ultra-low-noise mode and particularly in ultra-low-distortion mode.

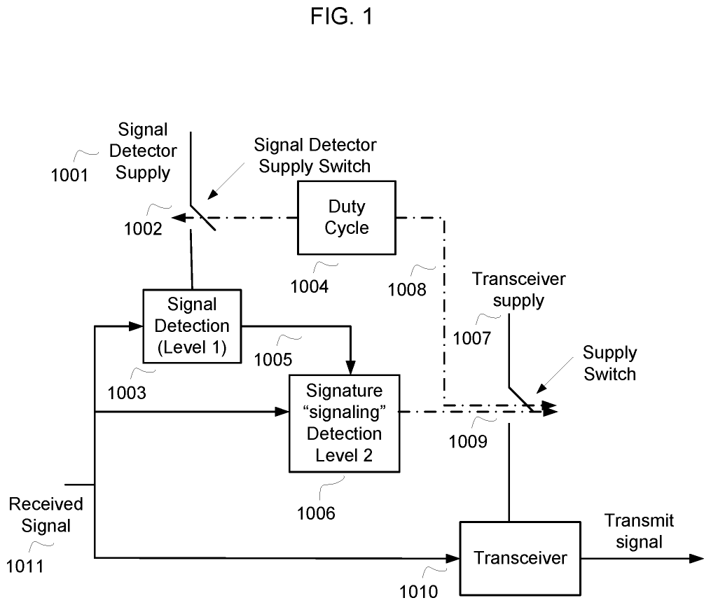

FIG. 1 is a simplified block diagram of a wakeup receiver circuit, according to one exemplary embodiment.

The wakeup receiver circuit may include a signal supply 1001 connected to signal detection level 1 1003 for detection of signal presence 1011 at some bandwidth. If signal detection level 1 1003 determines that a signal exist is provides signal 1005, which turns on a signature/valid marker detection circuit 1006. Signature/valid marker detection circuit 1006 may consume high power. If signature/valid marker detection circuit 1006 determines that the marker is valid it provides signal 1009 to switch on the transceiver power supply 1007, turning on the transceiver 1010. Alternatively, the wakeup receiver may periodically turn on the signal detection power supply using signal 1002. At that time the signal 1011 presence testing is done.

As stated above, although the design of the wakeup receiver circuit of FIG. 1 looks promising, implementing a periodical turn-on wakeup receiver using, for example, Bluetooth low energy (BLE), may result in a delayed-response transceiver. Additionally, such receiver may consume a lot of power. For example, in the BLE case a battery based wakeup receiver such as described with reference to FIG. 1 may last 8-14 months using a CR2032 battery. Furthermore, the CR2032 battery may be too big for some devices, such as eyeglasses, button of pens or shirts, or toothbrush. Moreover, even if an envelope detector is implemented, the number of false alarms will be high, as ISM band is very dense and noisy. Therefore, it would not be easy to implement a bandwidth signal presence envelope detector.

Still there is a requirement for some devices to work for a few years and using a battery much smaller than the CR2032 (a 235mah battery). Acoustic communication may allow a battery wakeup receiver to last few years using the acoustic band of 14000 Hz-2000 Hz, and particularly if the 6000 Hz band is divided into smaller bands like 500 Hz. Acoustic communication may consume 2000 times less power compared with RF communication.

A microphone is the common acoustic signal transducer. A common microphone consumes 17 μA-500 μA. For example, a battery of 2.5 mm×2.5 mm×1 mm has a volume 160 times smaller than the CR2032 battery (with a diameter of 20 mm and thickness of 3 mm) and therefore may supply about 1.47 mAh (compared with the 235 mAh of the CR2032). Therefore a microphone consuming 17 μA may consume the small battery (2.5 mm×2.5 mm×1 mm) in about 90 hours.

Moreover, a common microphone may have Signal to Noise Ratio (SNR) of about 68 dB, which may limit the communication range. Therefore there is a need to have extremely low power wakeup receiver. Such receiver should consume 50 nWatts-100 nWatts. Using a 3V battery this may result in 17 nA-33 nA, which may provide about 10 years of operation (for power consumption of 50 nWatts).

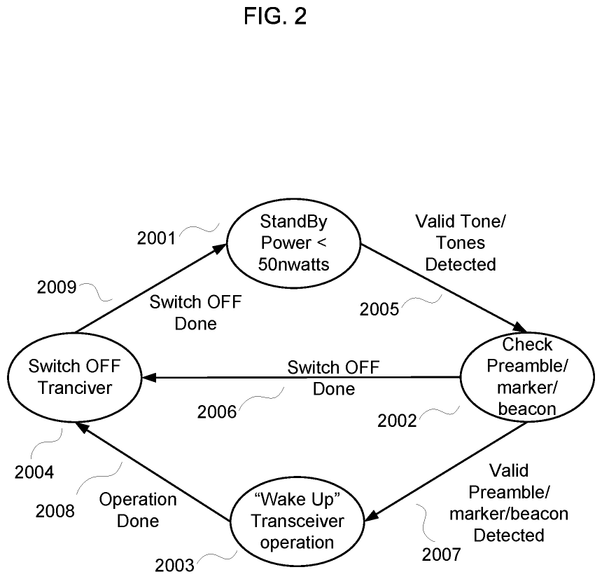

FIG. 2 is a simplified state machine of an acoustic wakeup transceiver, according to one exemplary embodiment.

In FIG. 2, the first state 2001 may consume 50 nWatts. This state may search for an acoustic signal using an ultra-low power microphone, and an ultra-low power signal detection circuit, which is feasible using extremely low frequency of the acoustic signal. When an acoustic signal presence is detected (step 2005), the state machine moves to the check preamble/marker/beacon state 2002. If this was a false alarm 2006, the state machine goes to the switch-off state 2004, sends a switch off signal 2009, and goes back to the first state 2001. If the preamble/marker/beacon is valid (step 2007), the acoustic transceiver wakes-up and the state machine goes to the “Wakeup” state 2003, where the transceiver performs the required operation

As suggested above the acoustic based transceivers, for example of an IoT or IoE device, may need to work only “On Demand”. Therefore such transceiver may be in standby state 2001 most of the time. The acoustic wakeup signal may be a tone or combinations of tones.

To use microphone as “receive antenna” for IoT or IoE devices, the microphones should have low distortion. As a microphone used for IoT or IoE devices sense the audio environment as well as the acoustic communication signal. Such acoustic communication signal may use a frequency band starting at 15000 Hz and above. While the audio environment may be very noisy, it is much less noisy in the upper frequency domain where the acoustic IoT IoE devices may operate. However, higher order distortion elements (e.g., 2nd, 3^{rd}, etc.) may appear in the upper frequency band, and hence may create noise for the acoustic communication devices.

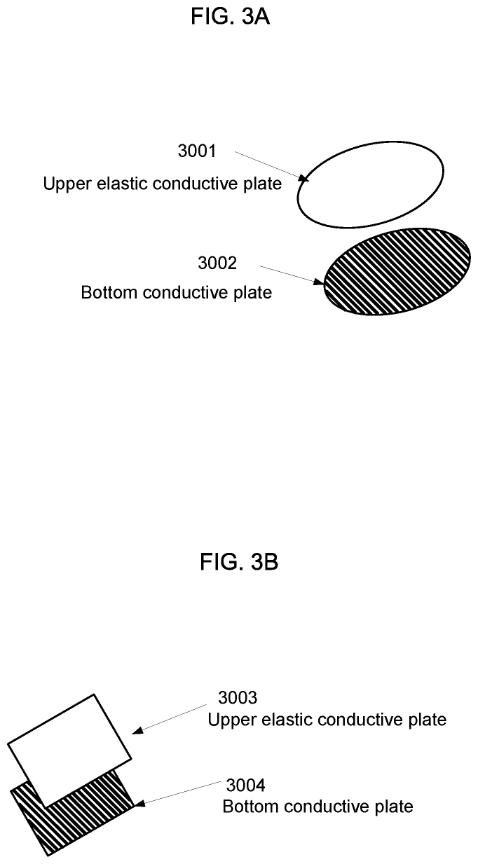

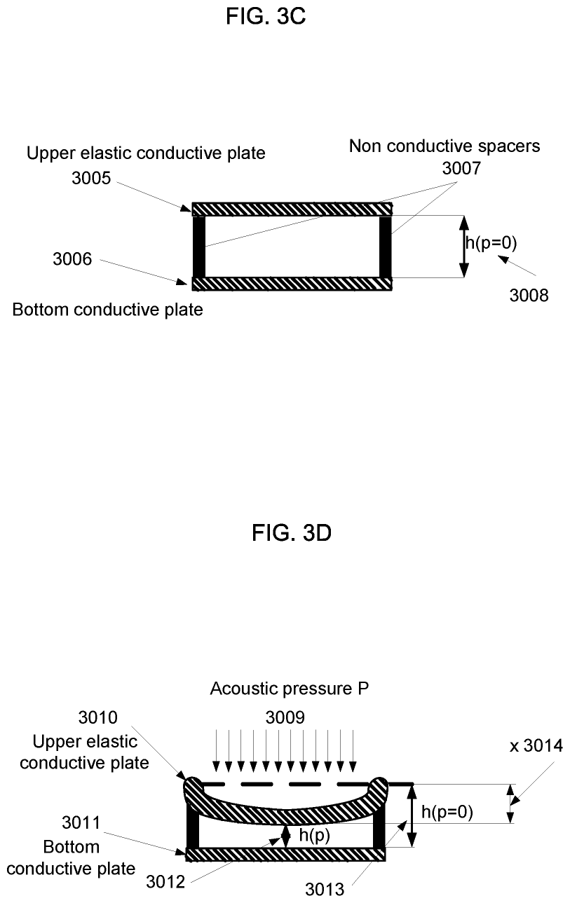

FIG. 3A is a simplified illustration of a round-plates MEMS microphone capacitor element, according to one exemplary embodiment. FIG. 3A shows a round upper elastic conductive plate 3001 and a round bottom conductive plate 3002.

FIG. 3B is a simplified illustration of a square-plates MEMS microphone capacitor element, according to one exemplary embodiment. FIG. 3B shows a square upper elastic conductive plate 3003 and a square bottom conductive plate 3004.

FIG. 3C is a simplified illustration of a side view of MEMS capacitor element at rest, according to one exemplary embodiment. FIG. 3C shows an upper elastic conductive plate 3005 separated from bottom conductive plate 3006 by one or more by non-conductive spacers 3007 by a typical distance (or height at zero pressure) 3008 of h(p=0).

FIG. 3D is a simplified illustration of a side view of MEMS capacitor when pressure is applied to the elastic conductive plate (membrane), according to one exemplary embodiment. FIG. 3D shows an upper elastic conductive plate 3010 and bottom conductive plate 3011. The elastic conductive plate 3010 is bent by acoustic pressure P 3009 so that the minimal distance from the bottom conductive plate 3011 is h(p), and the curvature distance 3014 is h(p−0) minus h(p).

The term “upper” and/or “bottom” relates to the relative position in the respective figure and does not imply that the respective plate is necessarily above or below the other plate. The term “upper” may be replaced by the term “elastic” and the term “bottom” may be replaced by “fix” or “fixed”. However, not implying that the upper plate is necessarily elastic and/or that the “bottom” plate is necessarily fix or fixed. Nevertheless, one of the plate may be elastic and at least one another plate may be fix or fixed.

Both MEMS and ECM microphones may be based on an elastic conductive plate (or membrane, or diaphragm), such as plates 3001, 3003, 3005, and 3010 of FIGS. 2A, 3B, 3C, and 3D, respectively, and a parallel conductive fixed plate, such as plates 3002, 3004, 3006, and 3011 of FIGS. 2A, 3B, 3C, and 3D, respectively.

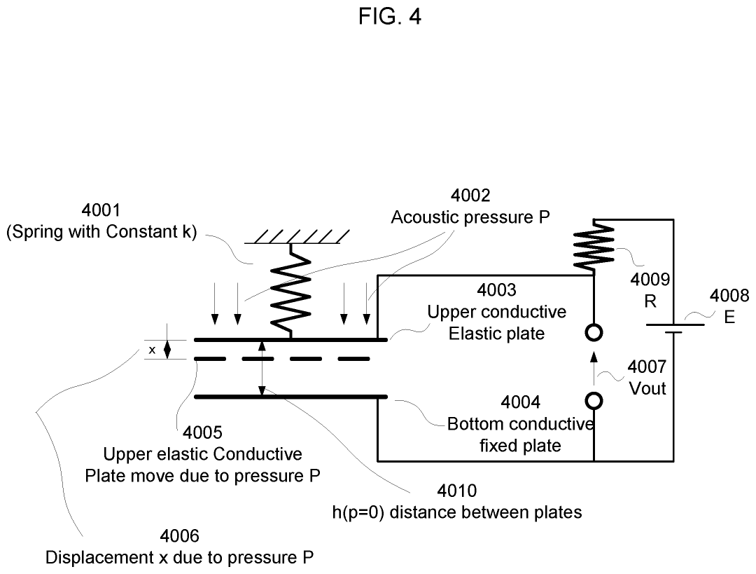

Based on “Review on The Modeling of Electrostatics MEMS” by Wan-Chun et al, (available from MDPI AG, Klybeckstrasse 64, 4057 Basel, Switzerland) the upper elastic conductive plate and bottom fixed conductive plate may be modeled using a spring model as described in FIG. 4.

FIG. 4 is a simplified illustration of an electronic circuit providing a dynamic model of a capacitor based Microphone (MEMS or ECM) upper plate, according to one exemplary embodiment.

FIG. 4 describes the force on the upper elastic conductive plate 4003 and/or 4005 by a spring 4001 having a constant k, due to pressure P 4002. The upper plate 4003 will move down by a distance x (4006) to a position 4005.

The capacitor formed by the upper plate 4003 and lower plate 4004 is connected to an electronic circuit via resistor R and voltage source E 4008, this circuit model is more suitable for MEMS microphones, but the analysis below is suitable for ECM microphones as well.

With a large resistor R, and assuming that the capacitance at rest is Co, after some time we have charge on the microphone capacitor equal to:

Q=EC₀ Eq. 1

With a pressure P applied to the upper plate we have:

F=PA Eq. 2

where A is the area of the upper plate.

Note that the area of the upper plate changes according to FIG. 3D 3010. This is one source of distortion.

Due to this pressure P or force F the upper plate moves down by x, where

F=PA=kx Eq. 3

Where x is very small compared to h, 4010 the distance between the plates, according to Eq. 4.

$$Q = {EC}_{0} = ( E + Δ V ) ( {C}_{0} + Δ C ) ⇒ Δ V = - E \frac{Δ C}{{C}_{0}} = - E \frac{A {ɛ}_{0} ( \frac{1}{h - x} - \frac{1}{h} )}{A {ɛ}_{0} \frac{1}{h}} \approx - E \frac{x}{h} = - E \frac{( \frac{PA}{k} )}{h} \qquad Eq . 4$$

According to Eq. 4, the variation of the output voltage Vout 4007 is proportional to the pressure of the acoustic wave. This assumes that the upper plate 4002 moves up or down based on the spring 4001 model of FIG. 4.

In practice, the variation in the output voltage Vout 4007 may not have a linear relation to the acoustic pressure P 4002, as described by Eq. 4.

In U.S. Pat. No. 6,526,149 B1 “System and Method for Reducing Non Linear Electrical distortion in Electrostatic Device” it has been shown that:

$${C}_{0} + Δ C = {C}_{0} \frac{h ( p = 0 )}{x} ln ( 1 + \frac{x}{h ( p = 0 )} ) \qquad Eq . 5$$

And if we expand around x=0 we get

$$\begin{matrix}\begin{matrix}{C}_{0} + Δ C = {C}_{0} \frac{h ( p = 0 )}{x} [ \begin{matrix}\frac{x}{h ( p = 0 )} - \frac{1}{2} {( \frac{x}{h ( p = 0 )} )}^{2} + \\ \frac{1}{3} {( \frac{x}{h ( p = 0 )} )}^{3} + …\end{matrix} ] \\ = {C}_{0} + {C}_{0} [ \begin{matrix}- \frac{1}{2} ( \frac{x}{h ( p = 0 )} ) + - \frac{1}{3} {( \frac{x}{h ( p = 0 )} )}^{2} - \\ \frac{1}{4} {( \frac{x}{h ( p = 0 )} )}^{3} + …\end{matrix} ]\end{matrix} \\ Using Eq . 4 one can derive that \text{:} & Eq . 6 \\ Δ V = - E \frac{Δ C}{{C}_{0}} = E [ \frac{1}{2} ( \frac{x}{h ( p = 0 )} ) ] + E [ \frac{1}{3} {( \frac{x}{h ( p = 0 )} )}^{2} - \frac{1}{4} {( \frac{x}{h ( p = 0 )} )}^{3} + … ] & Eq . 7\end{matrix}$$

Showing the 2^{nd}, 3^{rd} etc., nonlinear distortion terms.

Which is the basis for a method for reducing the non-linear distortion resulting from the non-linearity of a capacitive-based microphone diaphragm. The device and/or the method for a low-distortion microphone may therefore include a first fixed conductive plate, a second elastic conductive plate (a membrane), an electronic interface and bias circuit connected to the first and second conductive plates having an output signal that indicates the temporal capacitance of the first and second conductive plates, a controller having an temporal capacitance indication input, a control gain output signal, and a variable-gain amplifier having an input, output and a gain control input connected with its input to the conductive plates, and its control input to the controller control gain output.

According to another exemplary embodiment provided a microphone including a first fixed conductive plate, a second elastic conductive plate the membrane, an electret placed between the conductive plates forming Electrets Condenser Microphone, an electronic interface and bias circuit connected to the first and second conductive plates having an output signal that indicates the temporal capacitance of the first and second conductive plates, a controller having an temporal capacitance indication input, a control gain output signal, and a variable-gain amplifier having an input, output and a gain control input connected with its input to the conductive plates, and its control input to the controller control gain output.

According to yet another exemplary embodiment provided a microphone including a first fixed conductive plate, a second elastic conductive plate the membrane, a first impedance having two nodes, connected with its first node to one of the conductive plates and with its second node to a microphone bias voltage, a variable-gain amplifier having an input signal node, output signal node and an input control node for the purpose of changing the gain connected with its input signal to the junction of the first impedance and one of the conductive plates, a test signal, a second impedance connected with its first node to the other conductive plate and with its second node to the test signal, and a controller having an input signal indicating the temporal capacitance, and output control signal, connected with its input indication signal to the junction of the second impedance and the other conductive plate and with its control output to the controller control input.

According to still another exemplary embodiment provided a microphone including a first fixed conductive plate, a second elastic conductive plate the membrane, an electret placed between the conductive plates forming Electrets Condenser Microphone, a variable-gain amplifier having an input signal node, output signal node and an input control node for the purpose of changing the gain connected with its input signal to one of the conductive plates, a test signal, a second impedance connected with its first node to the other conductive plate and with its second node to the test signal, and a controller having an input signal indicating the temporal capacitance, and output control signal, connected with its input indication signal to the junction of the second impedance and the other conductive plate and with its control output to the controller control input.

As one can see by Eq. 7 the signal due to the power or movement of the membrane x 3014 is given by a linear term

$$E [ \frac{1}{2} ( \frac{x}{h ( p = 0 )} ) ]$$

and a sum of nonlinear terms

$$E [ \frac{1}{3} {( \frac{x}{h ( p = 0 )} )}^{2} - \frac{1}{4} {( \frac{x}{h ( p = 0 )} )}^{3} + … ] .$$

The microphone response may be described using a Taylor series and the voltage variation as a function of the incident acoustic pressure could be described by:

ΔV(P)=a₀P+a₁P²+a₂P³+ . . . +aₙ₋₁Pⁿ Eq. 8

Where a₀P represents the linear term and a₁P²+a₂P³+ . . . +aₙ₋₁Pⁿ represents the non-linear terms.

Eq. 8 may be also written as:

$$\begin{matrix}Δ V ( P ) = {a}_{0} P [ 1 + ( \frac{{a}_{1}}{{a}_{0}} ) P + ( \frac{{a}_{2}}{{a}_{0}} ) {P}^{2} + + ( \frac{{a}_{3}}{{a}_{0}} ) {P}^{3} + … + ( \frac{{a}_{n - 1}}{{a}_{0}} ) {P}^{n - 1} ] \\ = {a}_{0} P [ 1 + f ( P ) ]\end{matrix} \qquad Eq . 9$$

The non-linear term [1+f(P)] is the distortion gain, which may be calculated for each P and then dynamically multiply the ΔV of Eq. 8 by

$$\frac{1}{[ 1 + f ( P ) ]} ,$$

which is the inverse of the distortion gain (1 divided by the distortion gain).

This may give:

$$Δ {V}_{compensated} ( P ) = Δ V ( P ) \frac{1}{[ 1 + f ( P ) ]} = {a}_{0} P [ 1 + f ( P ) ] \frac{1}{[ 1 + f ( P ) ]} = {a}_{0} P \qquad Eq . 10$$

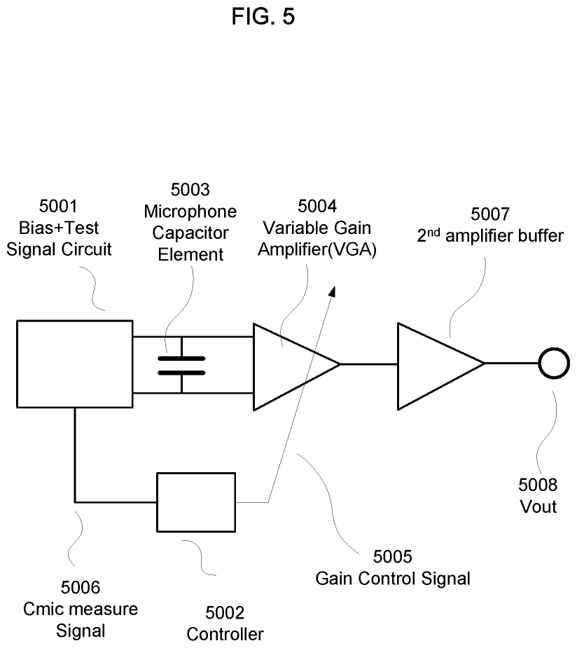

FIG. 5 is a simplified illustration of an ultra-low distortion microphone buffer basic diagram, according to one exemplary embodiment.

As discussed above, the distortion may depend on the displacement of the diaphragm 3014 x, as described by Eq. 7. For a typical microphone such as MEMS, ECM round plate, square plate, etc., the voltage variation equation (similar to Eq. 8) may be extracted. This parameters of the equation may depend on the microphone type, plate shape and other features. The parameters of Eq. 8 are known within the variations resulting from the process. For example, if h(p=0)=50 μm, a process error could be +/−300 nm, which is about 0.6%.

Also, for every P there is unique shift x, and unique capacitance. Referring to FIG. 3D, the diaphragm 3010, which has a parabolic shift, has a displacement of x in the center. In this case the capacitance is high. Moreover, it is clear that per each displacement x we have unique capacitance. Therefore, by measuring the temporal capacitance we may be able to determine the P or X, and hence determine

$$\frac{1}{[ 1 + f ( P ) ]}$$

### as in Eq. 10.

Returning to FIG. 4, the variable microphone capacitor 5003 is connected to a bias circuit and test signal 5001, the bias circuit is needed in the case of MEMS microphone to give initial polarization or charge. A test signal may be used to measure of the capacitance via signal which reflects the capacitance 5006. This signal is analyzed by the controller 5002 which may determine the capacitance value and hence determine

$$\frac{1}{[ 1 + f ( P ) ]} .$$

A control signal 5005 which is used to change the gain of a VGA 5004 is set to have again of

$$\frac{1}{[ 1 + f ( P ) ]} .$$

The output of the VGA 5004 may be connected to a second amplifier/buffer 5007.

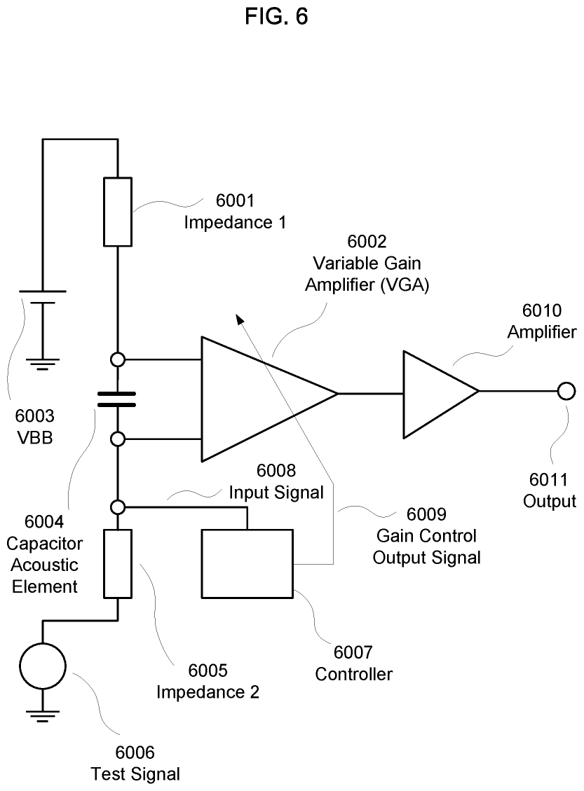

FIG. 6 is a simplified illustration of an ultra-low distortion microphone buffer circuit, according to one exemplary embodiment.

FIG. 6 may be used with a MEMS microphone. For an ECM microphone, the bias voltage 6003 and impedance 1 6001 may not be needed.

As shown in FIG. 6, the variable capacitor element 6004 first terminal is connected to a bias voltage VBB 6003 via impedance 1 6001, which could be comprised using resistors, inductors and or diodes or combinations to get low noise impedance, while the second terminal of the variable capacitor 6004 is connected to a test signal 6006 via impedance 2, a test signal could be for example high frequency sine wave, square wave that will not interferer the normal band of the microphone in one hand and would allow to measure the impedance of the variable capacitor 6004 via steady state amplitude or via analyzing transitions as a response to a square wave or any other parameter which the variable capacitance 6004 affects, the signal which is analyzed to reflect the variable capacitor is taken from the node that connects the second impedance 6005 to the variable capacitor 6004, the signal 6008 is analyzed by the controller 6007, which determines the temporal capacitance value and hence would generate a gain control signal 6009 to change the VGA 6002 gain to

$$\frac{1}{[ 1 + f ( P ) ]}$$

hence significantly reduce the distortion.

Fast capacitance measurement may be implemented using a test signal of, for example, 1 MHz-10 MHz. Such frequency may eliminate interference with acoustic signal in the case of audio microphones operating in the range of 0-20,000 Hz, or microphones dedicated for acoustic communication in air or underwater in the range of 0-200,000 Hz.

The algorithm and method based on FIG. 5 and FIG. 6 is based on the following steps:

A. Use test signal to fast-measure the temporal C.

B. Using this C, and knowing the shape and physical dimensions of the microphone variable capacitor, extract

$$\frac{1}{[ 1 + f ( P ) ]} .$$

C. Generate a signal for a variable-gain amplifier that will cause a gain of

$$\frac{1}{[ 1 + f ( P ) ]} .$$

The above algorithm is based on knowing the capacitance at rest, basically due to temperature and process variations the capacitance at rest would not have a constant known value but would have some average value with variations.

Returning to Eq. 6 and Eq. 7, it is required to measure the temporal capacitance. Assuming

$${C}_{0} + Δ C = {C}_{0} \frac{h ( p = 0 )}{x} ln ( 1 + \frac{x}{h ( p = 0 )} ) \qquad ( see Eq . 5 )$$

it is clear that process variation results in variation of C₀, as described by Eq. 11:

$$( 1 + θ ) {C}_{0} + ΔC = ( 1 + θ ) {C}_{0} \frac{h ( p = 0 )}{x} ln ( 1 + \frac{x}{h ( p = 0 )} ) \qquad Eq . 11$$

The compensation would think that we are dealing with C₀, hence there would be deviation in the x estimation basically x is computed as follows:

$$C \approx {C}_{0} + {C}_{0} [ - \frac{1}{2} ( \frac{x}{h ( p = 0 )} ) ] ⇒ x = [ \frac{C - {C}_{0}}{{C}_{0}} ] ( - 2 h ( p = 0 ) ) \qquad Eq . 12$$

so if there are (1+θ) variation on C₀ one would get:

$$\begin{matrix}x = [ \frac{C - {C}_{0}}{{C}_{0}} ] ( - 2 h ( p = 0 ) ) = \\ = [ \frac{( 1 + θ ) {C}_{0} + ( 1 + θ ) {C}_{0} [ - \frac{1}{2} ( \frac{x}{h ( p = 0 )} ) ] - {C}_{0}}{{C}_{0}} ] \\ ( - 2 h ( p = 0 ) ) = x ( 1 + θ )\end{matrix} \qquad Eq . 13$$

Eq. 13 shows that process variation/temperature variations will cause the same variations to the x and hence if the compensation is based on approximate value to Eq. 7.

$$\begin{matrix}Δ V = - E \frac{Δ C}{{C}_{0}} \approx E [ \frac{1}{2} ( \frac{x}{h ( p = 0 )} ) ] + E [ \frac{1}{3} {( \frac{x}{h ( p = 0 )} )}^{2} ] = \\ = E [ \frac{1}{2} ( \frac{x}{h ( p = 0 )} ) ] ( 1 + \frac{2}{3} \frac{x}{h ( p = 0 )} )\end{matrix} \qquad Eq . 14$$

Therefore, for

$$\frac{1}{[ 1 + f ( P ) ]} = \frac{1}{( 1 + \frac{2}{3} \frac{x}{h ( p = 0 )} )} ,$$

and as x is measured with some deviations, we get:

$$\begin{matrix}\frac{1}{[ 1 + f ( P ) ]} = \frac{1}{[ 1 + {f}_{1} ( x ) ]} = \frac{1}{( 1 + \frac{2}{3} \frac{x}{h ( p = 0 )} ( 1 + θ ) )} \\ = \frac{1}{( 1 + \frac{2}{3} \frac{x}{h ( p = 0 )} + \frac{2}{3} \frac{x}{h ( p = 0 )} θ )} \approx \\ \approx \frac{1}{( 1 + \frac{2}{3} \frac{x}{h ( p = 0 )} )} ( 1 - \frac{\frac{2}{3} \frac{x}{h ( p = 0 )} θ}{1 + \frac{2}{3} \frac{x}{h ( p = 0 )}} ) \\ \approx \frac{1}{( 1 + \frac{2}{3} \frac{x}{h ( p = 0 )} )} ( 1 - \frac{2}{3} \frac{x}{h ( F = 0 )} θ )\end{matrix} \qquad Eq . 15 )$$

Applying the deviated compensation of Eq. 15 to Eq. 14 may give:

$$Δ V \frac{1}{( 1 + \frac{2}{3} \frac{x}{h ( p = 0 )} )} ( 1 - \frac{2}{3} \frac{x}{h ( p = 0 )} θ ) == E [ \frac{1}{2} ( \frac{x}{h ( p = 0 )} ) ] ( 1 - \frac{2}{3} \frac{x}{h ( p = 0 )} θ ) \qquad Eq . 16$$

Therefore decreasing the distortion element

$$\frac{2}{3} \frac{x}{h ( p = 0 )} of Eq . 14 to \frac{2}{3} \frac{x}{h ( p = 0 )} θ .$$

If, for example, for a distance of 50 μm between the plates of the variable capacitor and the variations are 0.5 μm then we decreased the distortion by 100 or the distortion could are decreased by 40 dB.

C₀ (1+θ) may be estimated via long average as

$$C ( x ) = ( 1 + θ ) {C}_{0} + Δ C ( x ) = ( 1 + θ ) {C}_{0} \frac{h ( p = 0 )}{x} ln ( 1 + \frac{x}{h ( p = 0 )} ) \approx , \approx ( 1 + θ ) {C}_{0} + ( 1 + θ ) {C}_{0} [ - \frac{1}{2} ( \frac{x}{h ( p = 0 )} ) ] \qquad Eq . 17$$

Therefore, the expected value of C over time will give C₀ (1+θ).

The controller 5002 or 6007 may perform time averaging and hence get an estimate value for the C₀ (1+θ).

The terms [1+f(P)] and

$$\frac{1}{[ 1 + f ( P ) ]}$$

may be generated using the following steps:

Estimating C₀(1+θ), where θ is the process variation (resulting from un accurate dimensions) via long average of the temporal capacitance. For example, by assuming C₀ and estimating the term C₀ (1+θ) or θ.

f(P) may be described as f₁(x), assuming the h(p=0) as known from the process. It can be shown that if there is an error in h(p=0) by some value (1+α), for example, if the real height is (1+α)h(p=0), then the resulted x may be multiplied by

$$\frac{1}{( 1 + α )}$$

to get f₁(x), or

$$\frac{1}{[ 1 + {f}_{1} ( x ) ]} .$$

Eq. 15 may then be used, using θ and h(p=0), while x is extracted using the expression for the temporal capacitance described by Eq. 17

$$( 1 + θ ) {C}_{0} \frac{h ( p = 0 )}{x} ln ( 1 + \frac{x}{h ( p = 0 )} )$$

The steps of the compensation algorithm is described below:

A) Estimate B using long average of the temporal capacitance C₀ (1+θ)+ΔC(x).

B) For every small amount of time (10 times higher in rate than the signal band width for example 500 Khz) calculate the temporal capacitance using the test signal.

C) Using Eq. 17 and the assumed h(p=0) from process knowledge calculate x.

D) Using Eq. 15, h(p=0), the estimate θ and the calculated temporal x calculate the function

$$\frac{1}{[ 1 + {f}_{1} ( x ) ]} .$$

E) Use this function to generate amplification to mitigate this distortion.

1-16. (canceled)

17. An acoustic sensor comprising:
at least one fixed conductive plate;
an elastic conductive plate;
an electric circuit connected to the fixed conductive plate and to the elastic conductive plate, providing a signal indicating temporal capacitance between the fixed conductive plate and to the elastic conductive plate;
a controller comprising an input terminal connected to the electric circuit and an output terminal providing gain-control output signal; and
a variable-gain amplifier comprising:
a first input terminal connected to the at least one fixed conductive plate;
a second input terminal connected to the elastic conductive plate;
a gain-control input terminal connected to the controller output; and
an output terminal.

18. The acoustic sensor according to claim 17, additionally comprising electret placed between the at least one fixed conductive plate and the elastic conductive plate forming Electrets Condenser Microphone.

19. The acoustic sensor according to claim 17, wherein the controller calculates the gain-control output signal according to the inverse of distortion gain.

20. The acoustic sensor according to claim 17, wherein the controller measures base-capacitance when no pressure is applied to the elastic plate and calculates temporal-distortion-gain based on the base-capacitance.

21. The acoustic sensor according to claim 17, wherein the controller calculates the gain-control output signal according to the inverse of distortion gain, wherein distortion gain is calculated according to 1+f(P), or the distortion correction gain is calculated according to
$$\frac{1}{1 + f ( P )} ,$$
and wherein distortion element f(P)=f₁(x) is calculated using a measurement of the temporal capacitance or the temporal plate distance x and plates geometry of the acoustic sensor.

22. An acoustic sensor comprising:
a fixed conductive plate;
an elastic conductive plate;
a variable-gain amplifier comprising:
a first input terminal connected to the at least one fixed conductive plate;
a second input terminal connected to the elastic conductive plate;
a gain-control input terminal; and
an output terminal;
a first impedance connected between one of the conductive plates and a bias voltage;
a second impedance connected between another of the conductive plates and a test signal generator; and
a controller comprising:
an input terminal connected to the connection between the second impedance and the other conductive plate, and
an output terminal connected to the gain-control input of the variable-gain amplifier.

23. The acoustic sensor according to claim 22, additionally comprising electret placed between the at least one fixed conductive plate and the elastic conductive plate forming Electrets Condenser Microphone.

24. The acoustic sensor according to claim 22, wherein the first impedance comprises at least one of:
at least one resistor;
at least one low-leakage diode;
a plurality of low-leakage diodes connected in series;
a pair of low-leakage diodes connected in parallel in opposite polarity;
a plurality of pairs of low-leakage diodes, wherein each pair of low-leakage diodes comprises two diodes connected in parallel in opposite polarity, and wherein the pairs of low-leakage diodes are connected in series; and
a plurality of pairs of low-leakage diodes, wherein each pair of low-leakage diodes comprises two diodes connected in parallel in opposite polarity, wherein the pairs of low-leakage diodes are connected in series, and wherein the plurality of pairs of low-leakage diodes is connected in parallel to a capacitor.

25. The acoustic sensor according to claim 22, wherein the second impedance comprises at least one of:
at least one resistor; and
an inductor.

26. The acoustic sensor according to claim 22, wherein the controller calculates the gain-control output signal according to the inverse of distortion gain.

27. The acoustic sensor according to claim 22, wherein the controller measures base-capacitance when no pressure is applied to the elastic plate and calculates temporal-distortion-gain based on the base-capacitance.

28. The acoustic sensor according to claim 22, wherein the controller calculates the gain-control output signal according to the inverse of distortion gain, wherein distortion gain is calculated according to 1+f(P), or the distortion correction gain is calculated according to
$$\frac{1}{1 + f ( P )} ,$$
and wherein distortion element f(P)=f₁(x) is calculated using a measurement of the temporal capacitance or the temporal plate distance x and plates geometry of the acoustic sensor.

29. A method for sensing an acoustic signal, the method comprising:
connecting an electric circuit to a fixed conductive plate of an acoustic sensor, and to an elastic conductive plate of the acoustic sensor, the electric circuit providing a signal indicating temporal capacitance between the fixed conductive plate and to the elastic conductive plate;
connecting an input terminal of a controller to the electric circuit, wherein an output terminal of the controller provides gain-control output signal; and
connecting the output terminal of the controller to a variable-gain amplifier;
connecting a first input terminal of the variable-gain amplifier to the at least one fixed conductive plate;
connecting a second input terminal of the variable-gain amplifier to the elastic conductive plate; and
connecting a gain-control input terminal of the variable-gain amplifier to the controller output;
deriving acoustic signal from an output terminal of the variable-gain amplifier.

30. The method according to claim 29, additionally comprising:
providing electret between the at least one fixed conductive plate and the elastic conductive plate forming Electrets Condenser Microphone.

31. The method according to claim 29, wherein the controller calculates the gain-control output signal according to the inverse of distortion gain.

32. The method according to claim 29, wherein the controller measures base-capacitance when no pressure is applied to the elastic plate and calculates temporal-distortion-gain based on the base-capacitance.

33. The method according to claim 29, wherein the controller calculates the gain-control output signal according to the inverse of distortion gain, wherein distortion gain is calculated according to 1+f(P), or the distortion correction gain is calculated according to
$$\frac{1}{1 + f ( P )} ,$$
and wherein distortion element f(P)=f₁(x) is calculated using a measurement of the temporal capacitance temporal plate distance x and microphone plates geometry.

34. A method for sensing an acoustic signal, the method comprising:
connecting a first input terminal of a variable-gain amplifier to at least one fixed conductive plate, and a second input terminal of the a variable-gain amplifier to an elastic conductive plate; and
connecting a first impedance between one of the conductive plates and a microphone bias voltage, and connecting a second impedance between another of the conductive plates and a test signal generator;
connecting an input terminal of a controller to the connection between the second impedance and the other conductive plate, and connecting an output terminal of the controller to a gain-control input of the variable-gain amplifier.

35. The method according to claim 34, additionally comprising:
providing electret between the at least one fixed conductive plate and the elastic conductive plate forming Electrets Condenser Microphone.

36. The method according to claim 34, wherein the first impedance comprises at least one of:
at least one resistor;
at least one low-leakage diode;
a plurality of low-leakage diodes connected in series;
a pair of low-leakage diodes connected in parallel in opposite polarity;
a plurality of pairs of low-leakage diodes, wherein each pair of low-leakage diodes comprises two diodes connected in parallel in opposite polarity, and wherein the pairs of low-leakage diodes are connected in series; and
a plurality of pairs of low-leakage diodes, wherein each pair of low-leakage diodes comprises two diodes connected in parallel in opposite polarity, wherein the pairs of low-leakage diodes are connected in series, and wherein the plurality of pairs of low-leakage diodes is connected in parallel to a capacitor;

37. The method according to claim 34, wherein the second impedance comprises at least one of:
at least one resistor; and
an inductor.

38. The method according to claim 34, wherein the controller calculates the gain-control output signal according to the inverse of distortion gain.

39. The method according to claim 34, wherein the controller measures base-capacitance when no pressure is applied to the elastic plate and calculates temporal-distortion-gain based on the base-capacitance.

40. The method according to claim 34, wherein the controller calculates the gain-control output signal according to the inverse of distortion gain, wherein distortion gain is calculated according to 1+f(P), or the distortion correction gain is calculated according to
$$\frac{1}{1 + f ( P )} ,$$
and wherein distortion element f(P)=f₁(x) is calculated using a measurement of the temporal capacitance temporal plate distance x and microphone plates geometry.
